(19) United States
(12) Patent Application Publication
(10) Pub. No.: US 2013/0175590 A1
(43) Pub. Date: Jul. 11, 2013

(54) SEMICONDUCTOR DEVICE, SEMICONDUCTOR SYSTEM, AND METHOD OF FABRICATING THE SEMICONDUCTOR DEVICE

(71) Applicant: Myoung-Soo Kim, Hwaseong-si (KR)

(72) Inventor: Myoung-Soo Kim, Hwaseong-si (KR)

(21) Appl. No.: 13/614,918

(22) Filed: Sep. 13, 2012

(30) Foreign Application Priority Data
Jan. 9, 2012 (KR) 10-2012-0002521

(51) Int. Cl. H01L 29/94

(52) U.S. Cl. 257/296; 257/532; 257/E29.345

(57) ABSTRACT

A semiconductor device includes: an element isolation region formed in a substrate that defines an active region, a conductive layer formed on the active region, a first insulating film formed between the active region and the conductive layer and having a first thickness, and a second insulating film formed between the active region and the conductive layer and spans at least part of a boundary between the active region and the element isolation region and having a second thickness which is greater than the first thickness.

This application claims priority from Korean Patent Application No. 10-2012-0002521 filed on Jan. 9, 2012 in the Korean Intellectual Property Office, the disclosure of which is incorporated herein by reference in its entirety.

### BACKGROUND

1. Field

Embodiments of the present inventive concepts relate to a semiconductor device, a semiconductor system, and a method of fabricating the semiconductor device.

2. Description of the Related Art

As the electronics industry develops, the demands on the reliability (such as operation continuity, operation uniformity, durability against an external environment) of a semiconductor device are increasing.

The reliability of a semiconductor device may be reduced by the degradation of characteristics of each component of the semiconductor device or the interference between various components. When a semiconductor device is fabricated, a plasma process (e.g., a physical vapor deposition (PVD) process or a sputtering process) may be used. Charges generated during a plasma process can be accumulated in the semiconductor device. Such charges may cause various defects. For example, the charges may reduce the reliability of a gate insulating film of a metal oxide semiconductor (MOS)-type capacitor.

### SUMMARY

Aspects in accordance with principles of inventive concepts provide a semiconductor device having improved reliability.

Aspects in accordance with principles of inventive concepts also provide a semiconductor system having improved reliability.

Aspects in accordance with principles of inventive concepts also provide a method of fabricating a semiconductor device having improved reliability.

In accordance with principles of inventive concepts a semiconductor device includes: an element isolation region formed in a substrate and defining an active region; a conductive layer formed on the active region; a first insulating film formed between the active region and the conductive layer and having a first thickness; and a second insulating film formed between the active region and the conductive layer and spanning at least part of a boundary between the active region and the element isolation region and having a second thickness that is greater than the first thickness.

According to another aspect in accordance with principles of inventive concepts, the first insulating film comprises a thermal oxide film, and the second insulating film comprises a chemical vapor deposition (CVD) film

According to another aspect in accordance with principles of inventive concepts, a region of the conductive layer overlaps the element isolation region, and contacts are formed on the overlapping region of the conductive layer.

According to another aspect in accordance with principles of inventive concepts, the active region comprises a first side and a second side parallel to one another, and the second insulating film comprises a first partial insulating film that covers at least part of the first side and a second partial insulating film that covers at least part of the second side.

According to another aspect in accordance with principles of inventive concepts, the conductive layer comprises a first partial conductive layer having a first width and a second partial conductive layer having a second width that is different from the first width, wherein the second partial conductive layer overlaps the element isolation region.

According to another aspect in accordance with principles of inventive concepts, the active region includes a groove cut into the active region, and the second partial conductive layer overlaps the groove.

According to another aspect in accordance with principles of inventive concepts, the first partial conductive layer overlaps the entire active region.

According to another aspect in accordance with principles of inventive concepts includes a first metal oxide semiconductor (MOS) transistor having a first operating voltage and a second MOS transistor having a second operating voltage that is lower than the first operating voltage.

According to another aspect in accordance with principles of inventive concepts a semiconductor device further includes a third MOS transistor having a third operating voltage that is lower than the second operating voltage.

According to another aspect in accordance with principles of inventive concepts a thickness of a first gate insulating film of the first MOS transistor is equal to the second thickness of the second insulating film, and a thickness of a second gate insulating film of the second MOS transistor is equal to the first thickness of the first insulating film.

According to another aspect in accordance with principles of inventive concepts a first well is formed in the active region, the first MOS transistor comprises a second well, and the second MOS transistor comprises a third well, wherein the first well and the third well are doped with the same dopants.

According to another aspect in accordance with principles of inventive concepts the first well and the third well are formed to the same depth.

According to another aspect in accordance with principles of inventive concepts parts of a lateral profile of the conductive layer are aligned with parts of a lateral profile of the second insulating film

According to another aspect in accordance with principles of inventive concepts the conductive layer is electrically connected to a metal line, and the metal line is electrically connected to a protection diode formed in the substrate.

According to another aspect in accordance with principles of inventive concepts the metal line is a metal line at a first level.

According to another aspect in accordance with principles of inventive concepts the element isolation region comprises a shallow trench isolation (STI) region.

According to another aspect in accordance with principles of inventive concepts the device is a capacitor.

According to another aspect in accordance with principles of inventive concepts a semiconductor device includes a capacitor, a first MOS transistor, and a second MOS transistor, wherein an operating voltage of the first MOS transistor is higher than an operating voltage of the second MOS transistor, the capacitor uses a first insulating film and a second insulating film as a capacitor insulating film, a first thickness of the first insulating film is equal to a thickness of a second gate insulating film of the second MOS transistor, and a second thickness of the second insulating film is equal to a thickness of a first gate insulating film of the first MOS transistor.

According to another aspect in accordance with principles of inventive concepts the capacitor is a MOS-type capacitor.

According to another aspect in accordance with principles of inventive concepts the capacitor is formed on an active region defined by an element isolation region, and the second insulating film spans at least part of a boundary between the element isolation region and the active region.

According to another aspect in accordance with principles of inventive concepts the capacitor further comprises a conductive layer that is formed on the first insulating film and the second insulating film and overlaps the element isolation region, wherein contacts are formed on a region of the conductive layer that overlaps the element isolation region.

According to another aspect in accordance with principles of inventive concepts the first insulating film comprises a thermal oxide film, and the second insulating film comprises a CVD oxide film

According to another aspect in accordance with principles of inventive concepts parts of a lateral profile of the conductive layer are aligned with parts of a lateral profile of the second insulating film.

According to another aspect in accordance with principles of inventive concepts a semiconductor device includes a plurality of capacitors and at least one protection diode that protects the capacitors by discharging charges generated by a plasma process, wherein each of the capacitors includes: an element isolation region formed in a substrate and defining an active region; a conductive layer formed on the active region; a first insulating film formed between the active region and the conductive layer and having a first thickness; and a second insulating film formed between the active region and the conductive layer and spans at least part of a boundary between the active region and the element isolation region and having a second thickness that is greater than the first thickness.

According to another aspect in accordance with principles of inventive concepts the conductive layer of each of the capacitors is electrically connected to the at least one protection diode by a metal line.

According to another aspect in accordance with principles of inventive concepts the metal line is a metal line at a first level.

According to another aspect in accordance with principles of inventive concepts the capacitors are divided into a plurality of capacitor groups, and at least one protection diode is provided for each capacitor group.

According to another aspect in accordance with principles of inventive concepts the first insulating film comprises a thermal oxide film, and the second insulating film comprises a CVD oxide film.

According to another aspect in accordance with principles of inventive concepts the capacitors and the at least one protection diode are formed on the same substrate.

According to another aspect in accordance with principles of inventive concepts the capacitors are connected in parallel to each other.

According to another aspect in accordance with principles of inventive concepts semiconductor system includes a semiconductor chip and a module that are electrically connected to each other, wherein the semiconductor chip comprises at least one internal wiring for delivering an internal voltage and at least one capacitor electrically connected to the at least one internal wiring and stabilizing the internal voltage, and the capacitor includes: an element isolation region formed in a substrate and defining an active region; a conductive layer formed on the active region; a first insulating film formed between the active region and the conductive layer and having a first thickness; and a second insulating film formed between the active region and the conductive layer and on at least part of a boundary between the active region and the element isolation region and having a second thickness that is greater than the first thickness.

According to another aspect in accordance with principles of inventive concepts the semiconductor chip is a display drive IC (DDI).

According to another aspect in accordance with principles of inventive concepts the semiconductor chip comprises a voltage generator that receives an external voltage and generates at least one internal voltage, and the at least one internal wiring is connected to the voltage generator.

According to another aspect in accordance with principles of inventive concepts at least one external wiring is connected to the at least one internal wiring; and an external capacitor is connected to the at least one external wiring.

According to another aspect in accordance with principles of inventive concepts a method of fabricating a semiconductor device includes: forming an element isolation region in a substrate to define an active region; forming a second insulating film, that has a second thickness, on at least part of a boundary between the element isolation region and the active region; forming a first insulating film, that has a first thickness smaller than the second thickness, on a portion of the active region exposed by the second insulating film; and forming a conductive layer on the first insulating film and the second insulating film.

According to another aspect in accordance with principles of inventive concepts the forming of the second insulating film uses a CVD method.

According to another aspect in accordance with principles of inventive concepts the forming of the first insulating film uses a thermal oxidation method.

According to another aspect in accordance with principles of inventive concepts the second thickness of the second insulating film is equal to a thickness of a first gate insulating film of a first MOS transistor having a first operating voltage, and the first thickness of the first insulating film is equal to a thickness of a second gate insulating film of a second MOS transistor having a second operating voltage that is lower than the first operating voltage.

According to another aspect in accordance with principles of inventive concepts a method of fabricating a semiconductor device includes: forming an element isolation region in a substrate and defining first through third regions in which a capacitor, a first MOS transistor and a second MOS transistor are to be formed, respectively; forming a fourth insulating film, that has a second thickness, on the substrate; forming a third insulating film, that has a first thickness smaller than the second thickness, on the substrate; and forming an electrode conductive layer on the third insulating film and the fourth insulating film, wherein the fourth insulating film covers at least part of a boundary between the element isolation region and the active region in the first region, covers the entire second region and exposes the entire third region, and the third insulating film covers exposed portions of the first region and the third region.

According to another aspect in accordance with principles of inventive concepts the forming of the fourth insulating film uses a CVD method.

According to another aspect in accordance with principles of inventive concepts the forming of the third insulating film uses a thermal oxidation method.

According to another aspect in accordance with principles of inventive concepts an apparatus, includes: an active region formed in a substrate; an isolation region surrounding the active well; a conductive layer formed over the active region; and an insulating film formed between the active well and conductive layer, wherein at least a portion of the insulating film is relatively thick and is formed along a portion of the boundary between the active and isolation regions.

According to another aspect in accordance with principles of inventive concepts the relatively thick portion of the insulating film is a high voltage gate oxide.

According to another aspect in accordance with principles of inventive concepts the relatively thick portion of the insulating film is a chemical vapor deposition oxide.

According to another aspect in accordance with principles of inventive concepts the insulating film includes a relatively thin portion that is a thermal oxide film.

According to another aspect in accordance with principles of inventive concepts the conductor is a poly gate.

According to another aspect in accordance with principles of inventive concepts the conductor is a metal gate.

According to another aspect in accordance with principles of inventive concepts an apparatus further includes: electrical contacts, wherein the contacts, insulator, active region and conductor layer are configured as a capacitor.

According to another aspect in accordance with principles of inventive concepts the relatively thin insulating film portion is from approximately 10 Å to 300 Å thick and the relatively thick insulating film portion is from approximately 300 Å to 1200 Å thick.

According to another aspect in accordance with principles of inventive concepts, an apparatus further includes: a semiconductor chip and a module that are electrically connected to each other, wherein the semiconductor chip comprises at least one internal wiring for delivering an internal voltage and at least one capacitor electrically connected to the at least one internal wiring and stabilizing the internal voltage.

According to another aspect in accordance with principles of inventive concepts the semiconductor chip is a display drive IC (DDI).

According to another aspect in accordance with principles of inventive concepts the semiconductor chip comprises a voltage generator that receives an external voltage and generates at least one internal voltage, and the at least one internal wiring is connected to the voltage generator.

### BRIEF DESCRIPTION OF THE DRAWINGS

The above and other aspects and features in accordance with principles of inventive concepts will become more apparent by describing in detail exemplary embodiments thereof with reference to the attached drawings, in which:

FIG. 1 is a layout view of a semiconductor device 1 according to a first exemplary embodiment in accordance with principles of inventive concepts.

FIG. 2 is a cross-sectional view taken along the line A-A of FIG. 1.

FIG. 3 is a layout view of a semiconductor device 2 according to a second exemplary embodiment in accordance with principles of inventive concepts.

FIG. 4 is a layout view of a semiconductor device 3 according to a third exemplary embodiment in accordance with principles of inventive concepts.

FIG. 5 is a layout view of a semiconductor device 4 according to a fourth exemplary embodiment in accordance with principles of inventive concepts.

FIG. 6 is a layout view of a semiconductor device 5 according to a fifth exemplary embodiment in accordance with principles of inventive concepts.

FIG. 7 is a circuit diagram of a semiconductor device 6 according to a sixth embodiment in accordance with principles of inventive concepts.

FIG. 8 is an example layout view based on the circuit diagram of FIG. 7.

FIG. 9 is an example cross-sectional view based on the circuit diagram of FIG. 7.

FIG. 10 is a circuit diagram of a semiconductor device 7 according to a seventh embodiment in accordance with principles of inventive concepts.

FIG. 11 is a cross-sectional view of a semiconductor device 8 according to an eighth embodiment in accordance with principles of inventive concepts.

FIG. 12 is a block diagram of a semiconductor system 11 according to a first exemplary embodiment in accordance with principles of inventive concepts.

FIG. 13 is a block diagram of a semiconductor system 12 according to a second exemplary embodiment in accordance with principles of inventive concepts.

FIGS. 14 through 16 are diagrams illustrating intermediate processes included in a method of fabricating the semiconductor device 1 according to the first exemplary embodiment in accordance with principles of inventive concepts.

FIGS. 17 through 20 are diagrams illustrating intermediate processes included in a method of fabricating the semiconductor device 5 according to the fifth exemplary embodiment in accordance with principles of inventive concepts.

### DETAILED DESCRIPTION OF THE EMBODIMENTS

Exemplary embodiments in accordance with principles of inventive concepts will now be described more fully with reference to the accompanying drawings, in which exemplary embodiments are shown. Exemplary embodiments in accordance with principles of inventive concepts may, however, be embodied in many different forms and should not be construed as being limited to the embodiments set forth herein; rather, these embodiments are provided so that this disclosure will be thorough and complete, and will fully convey the concept of exemplary embodiments to those of ordinary skill in the art. In the drawings, the thicknesses of layers and regions may be exaggerated for clarity. Like reference numerals in the drawings denote like elements, and thus their description may not be repeated.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of exemplary embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of exemplary embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Exemplary embodiments in accordance with principles of inventive concepts are described herein with reference to cross-sectional illustrations that are schematic illustrations of idealized embodiments (and intermediate structures) of exemplary embodiments. As such, variations from the shapes of the illustrations as a result, for example, of manufacturing techniques and/or tolerances, are to be expected. Thus, exemplary embodiments in accordance with principles of inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of exemplary embodiments.

Unless otherwise defined, all terms (including technical and scientific terms) used herein have the same meaning as commonly understood by one of ordinary skill in the art to which exemplary embodiments in accordance with principles of inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

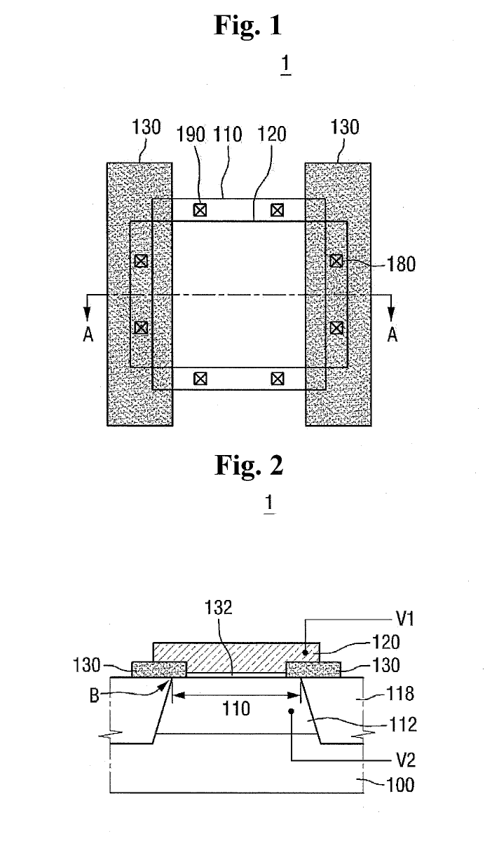

FIG. 1 is a layout view of a semiconductor device 1 according to a first exemplary embodiment in accordance with principles of inventive concepts. FIG. 2 is a cross-sectional view taken along the line A-A of FIG. 1.

Referring to FIGS. 1 and 2, the semiconductor device 1 according to the first exemplary embodiment in accordance with principles of inventive concepts may include a substrate 100, an element isolation region 118, a first well 112, a conductive layer 120, a first insulating film 132, a second insulating film 130, first contacts 180, and second contacts 190.

The element isolation region 118 may be formed in the substrate 100 to define an active region 110. The element isolation region 118 may be a shallow trench isolation (STI) region, for example.

The first well 112 may be formed in the active region 110. The first well 112 may be shallower than the element isolation region 118.

The conductive layer 120 may be formed on the active region 110. The conductive layer 120 may overlap at least part of the element isolation region 118. That is, the conductive layer 120 may be formed on at least part of a boundary B between the element isolation region 118 and the active region 110. The conductive layer 120 may be polysilicon, metal, or a stack of the same, for example

In this exemplary embodiment, the first contacts 180 are formed on the conductive layer 120. Specifically, the first contacts 180 may be formed on a portion of the conductive layer 120 that overlaps the element isolation region 118. In accordance with principles of inventive concepts, forming the first contacts 180 on a portion of the conductive layer 120 that overlaps the element isolation region 118 minimizes damage that may occur during the formation of the first contacts 180. A first voltage V1 may be applied to the conductive layer 120 via the first contacts 180.

The second contacts 190 are formed on the active region 110 (i.e., on the first well 112) to be electrically connected to the first well 112. A second voltage V2 may be applied to the first well 112 via the second contacts 190.

In the exemplary embodiment depicted in FIGS. 1 and 2, four first contacts 180 and four second contacts 190 are illustrated. However, the number of the first contacts 180 and the number of the second contacts 190 are not limited to four.

In this exemplary embodiment, the first insulating film 132 is formed between the active region 110 and the conductive layer 120 and has a first thickness. The first insulating film 132 may be a thermal oxide film, for example.

The second insulating film 130 may be formed between the active region 110 and the conductive layer 120 and on at least part of the boundary B between the active region 110 and the element isolation region 118.

The active region 110 may be, for example, rectangular. That is, the active region 110 may include a first side (e.g., a left side of the active region 110 in FIG. 1) and a second side (e.g., a right side of the active region 110 in FIG. 1) that face each other, or, are parallel to one another. The second insulating film 130 may include a first partial insulating film that covers at least part of the first side (e.g., the second insulating film 130 on the left side of FIG. 2) and a second partial insulating film (e.g., the second insulating film 130 on the right side of FIG. 2) that covers at least part of the second side.

In the drawings, the second insulating film 130 covers only part of the boundary B between the active region 110 and the element isolation region 118 (that is, the portions of the boundary B on the left side and right side of active region 110 in FIG. 1) in this exemplary embodiment. This configuration leaves open a region of the first well 112 that can be brought into contact with the second contacts 190. In an exemplary embodiment in accordance with principles of inventive concepts in which the second voltage V2 can be applied to the first well 112 using a method other than the second contacts 190, the second insulating film 130 may cover the whole of the boundary B.

The thickness of the second insulating film 130, also referred to herein as the second thickness of the second insulating film, may be greater than the thickness of the first insulating film 132, also referred to herein as the first thickness of the first insulating film 132. The second insulating film 130 may be a chemical vapor deposition (CVD) oxide film, for example. In an embodiment in which the semiconductor device 1 in accordance with principles of inventive concepts is a capacitor, the first insulating film 132 and the second insulating film 130 may serve as a capacitor insulating film. In an exemplary embodiment in accordance with principles of inventive concepts, second insulating film 130 is formed to a thickness that is sufficient to avoid breakdown effects that might otherwise occur. Because shallow trench isolation (STI) effects may limit the utility of a thermal oxidation approach, a method in accordance with principles of inventive concepts employs chemical vapor deposition (CVD) to form second insulating film 130 to an effective thickness. A relatively thick insulating film 130 formed on at least a part of the boundary B between active region 110 and isolation region 118 improves the reliability of the semiconductor device 1.

That is, a capacitor insulating film formed using thermal oxidation may exhibit thinning at the boundary B between the active region 10 and isolation region 118, due to an STI stress effect. Charges generated during a plasma process may be accumulated in such a thinner portion of the capacitor insulating film and, when first and second voltages V1 and V2 are applied to terminals of a capacitor (i.e., the conductive layer 120 and the first well 112), the thinner portion of the capacitor insulating film could be easily destroyed. A high voltage applied to the conductive layer 120 through the first contacts 180 could easily destroy the thinner portion of the capacitor insulating film located close to the first contacts 180. For these reasons, in an exemplary embodiment in accordance with principles of inventive concepts, a relatively thick insulating layer 130 is formed on at least a part of the boundary B between active region 110 and isolation region 118. A relatively thick insulating layer 130, which may be used in high voltage applications, may be obtained using a CVD process, for example, as just described. The relatively thick insulating layer 130 may be referred to herein as a high voltage gate oxide, for example.

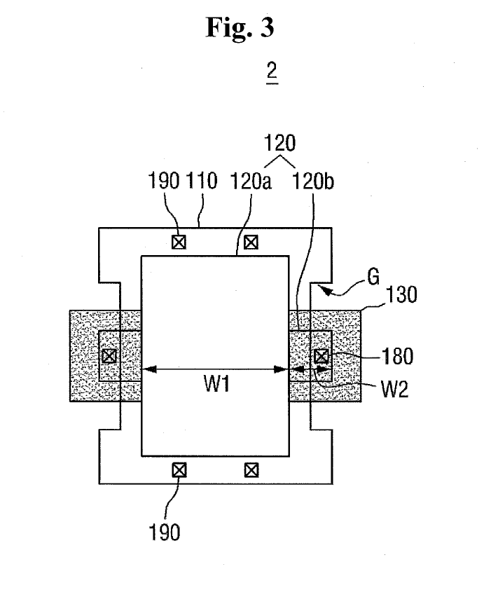

FIG. 3 is a layout view of a semiconductor device 2 according to a second exemplary embodiment in accordance with principles of inventive concepts. For simplicity, the following description will focus on differences from the above-described semiconductor device 1 according to the first exemplary embodiment in accordance with principles of inventive concepts.

Referring to FIG. 3, the semiconductor device 2 according to the second exemplary embodiment in accordance with principles of inventive concepts may include a groove G cut into an active region 110. In the drawing, the groove G is cut into the active region 110 from both sides of the active region 110, but embodiments in accordance with principles of inventive concepts are not limited thereto.

A conductive layer 120 may include a first partial conductive layer 120a having a first width W1 and a second partial conductive layer 120b having a second width W2 that is different from the first width W1. The first width W1 may be greater than the second width W2, as shown in the drawing, but embodiments in accordance with principles of inventive concepts are not limited thereto.

The entire first partial conductive layer 120a may overlap the active region 110, and the second partial conductive layer 120b may extend to overlap an element isolation region 118. In particular, the second partial conductive layer 120b may overlap the groove G. First contacts 180 may be formed on the second partial conductive layer 120b.

A second insulating film 130 may be formed on at least part of a boundary B between the second partial conductive layer 120b and the element isolation region 118.

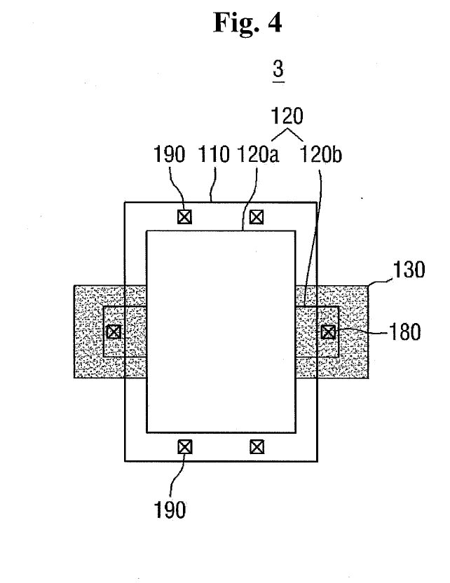

FIG. 4 is a layout view of a semiconductor device 3 according to a third exemplary embodiment in accordance with principles of inventive concepts. For simplicity, the following description will focus on differences from the above-described semiconductor device 2 according to the second exemplary embodiment in accordance with principles of inventive concepts.

Referring to FIG. 4, in the semiconductor device 3 according to the third exemplary embodiment in accordance with principles of inventive concepts, an active region 110 may not include a groove (see ‘G’ in FIG. 3). A conductive layer 120 may include a first partial conductive layer 120a having a first width W1 and a second partial conductive layer 120b having a second width W2 that is different from the first width W1. In accordance with principles of inventive concepts, a second insulating film 130 may be formed on at least part of a boundary B between the second partial conductive layer 120b and an element isolation region 118.

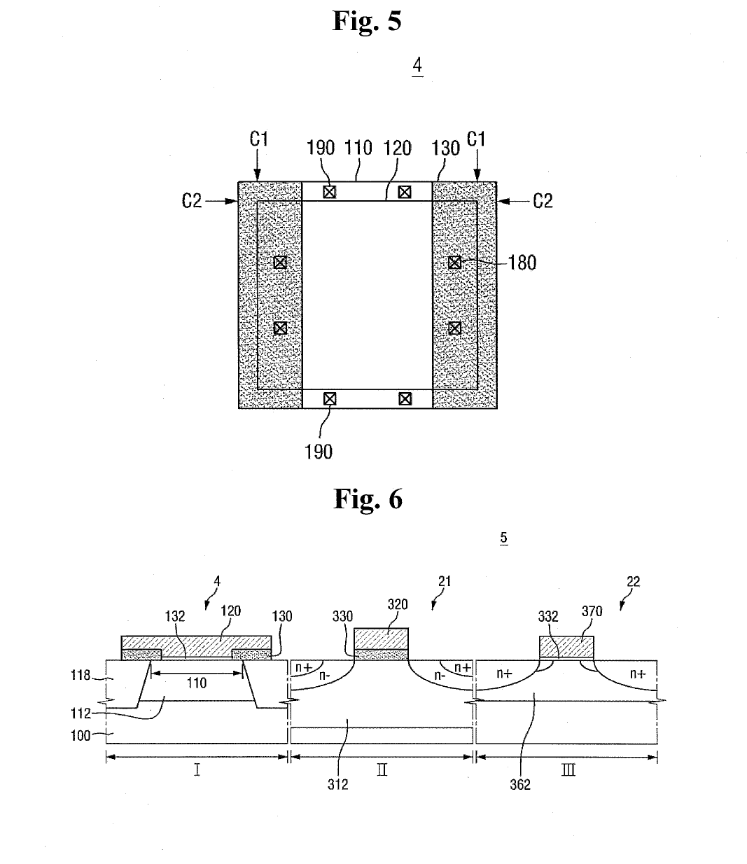

FIG. 5 is a layout view of a semiconductor device 4 according to a fourth exemplary embodiment in accordance with principles of inventive concepts. For simplicity, the following description will focus on differences from the above-described semiconductor device 1 according to the first exemplary embodiment in accordance with principles of inventive concepts.

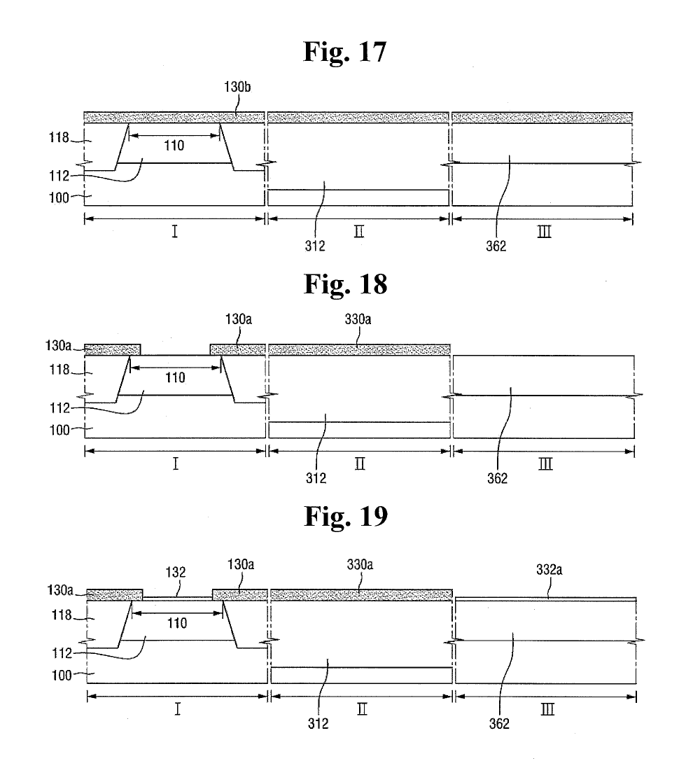

Referring to FIG. 5, in the semiconductor device 4 according to the fourth exemplary embodiment in accordance with principles of inventive concepts, parts C1 and C2 of a lateral profile of a second insulating film 130 may be aligned with parts C1 and C2 of a lateral profile of an active region 110. Accordingly, the number of masks used to fabricate the semiconductor device 4 according to the fourth exemplary embodiment in accordance with principles of inventive concepts can be reduced, as will be described later with reference to FIGS. 17 through 20.

FIG. 6 is a layout view of a semiconductor device 5 according to a fifth exemplary embodiment in accordance with principles of inventive concepts.

Referring to FIG. 6, the semiconductor device 5 according to the fifth exemplary embodiment in accordance with principles of inventive concepts includes a capacitor 4 formed in a first region I, a first metal oxide semiconductor (MOS) transistor 21 formed in a second region II, and a second MOS transistor 22 formed in a third region III. The capacitor 4 may be implemented as any of the above-described semiconductor devices 1 through 4 according to the first through fourth exemplary embodiments in accordance with principles of inventive concepts.

In an exemplary embodiment in accordance with principles of inventive concepts, the capacitor 4 may be a MOS-type capacitor that includes an active region 110 defined by an element isolation region 118, a first well 112 formed in the active region 110, and a conductive layer 120 formed on the active region 110. A first insulating film 132 and a second insulating film 130 may be used as a capacitor insulating film. The first insulating film 132 may be formed between the first well 112 and the conductive layer 120, and the second insulating film 130 may be formed between the first well 112 and the conductive layer 120, and on at least part of a boundary between the element isolation region 118 and the active region 110.

The first MOS transistor 21 may be a high-voltage transistor and the second MOS transistor 22 may be a medium-voltage transistor or a low-voltage transistor.

The high-voltage transistor may have an operating voltage of from 8V to 200 V, more specifically, 20 V, 30 V, or 50 V, for example. The medium-voltage transistor may have an operating voltage of from 3V to 8 V, more specifically, 3 V or 5.5 V, for example. The low-voltage transistor may have an operating voltage of 3 V or less, for example.

Because the high-voltage transistor has a higher operating voltage than the medium-voltage transistor or the low-voltage transistor, a first gate insulating film 330 is thicker than a second gate insulating film 332. For example, if the first gate insulating film 330 has a thickness of from 300 Å to 1200 Å, the second gate insulating film 332 may have a thickness of from 10 Å to 300 Å.

In addition, in an exemplary embodiment in accordance with principles of inventive concepts, the first gate insulating film 330 may be a CVD oxide film, and the second gate insulating film 332 may be a thermal oxide film, for example.

Because the high-voltage transistor has a higher operating voltage than the medium-voltage transistor or the low-voltage transistor, a second well 312 may be deeper than a third well 362.

In an exemplary embodiment in accordance with principles of inventive concepts, source/drain of the high-voltage transistor may have, for example, a mask islanded double diffused drain (MIDDD) structure, and a source/drain of the medium-voltage transistor or the low-voltage transistor may have, for example, a lightly diffused drain (LDD) structure.

The first well 112 of the capacitor 4 and the third well 362 of the second MOS transistor 22 may be doped with the same dopants and have the same depth, for example. The first insulating film 132 of the capacitor 4 and the second gate insulating film 332 of the second MOS transistor 22 may be formed of the same material to the same thickness. In addition, the second insulating film 130 of the capacitor 4 and the first gate insulating film 330 of the first MOS transistor 21 may be formed of the same material to the same thickness. That is, the capacitor 21 may be formed when the first MOS transistor 21 and the second MOS transistor 22 are formed, for example.

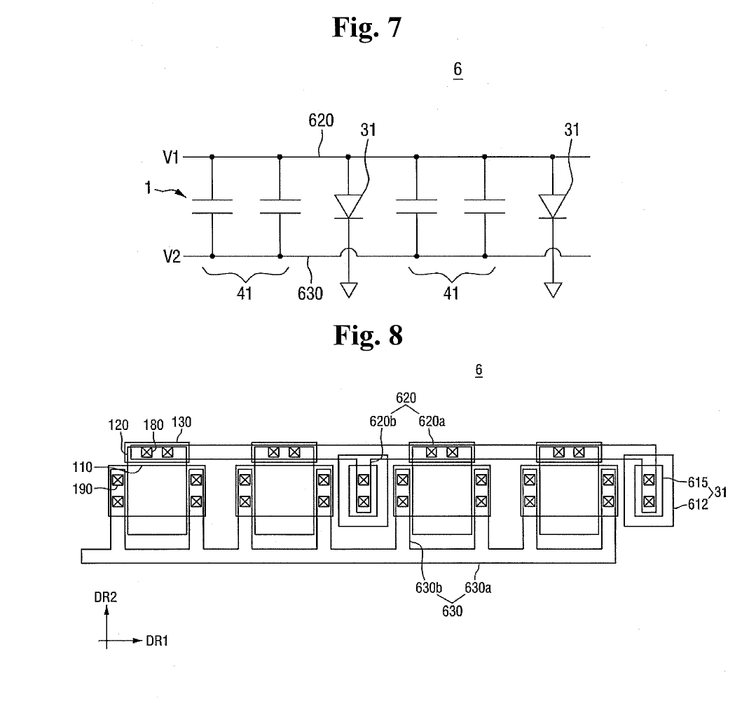

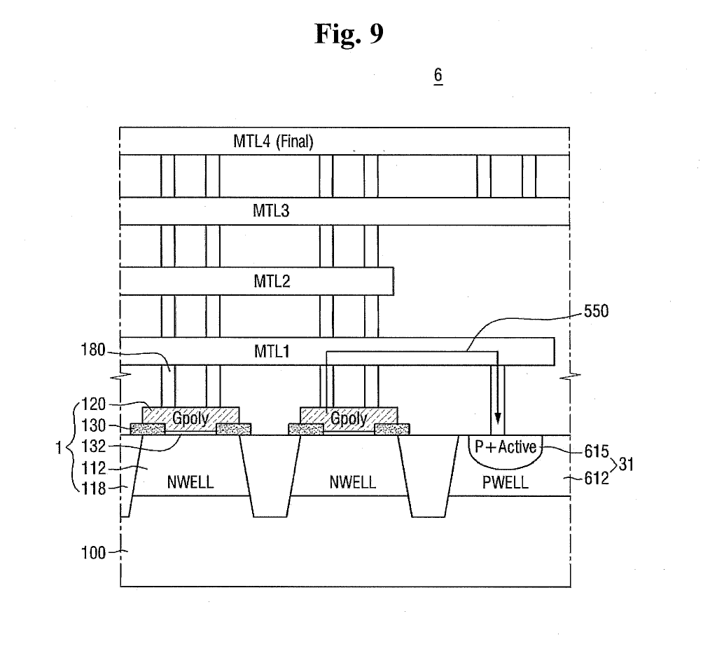

FIG. 7 is a circuit diagram of a semiconductor device 6 in accordance with principle of inventive concepts; FIG. 8 is an example layout view based on the circuit diagram of FIG. 7; and FIG. 9 is an example cross-sectional view based on the circuit diagram of FIG. 7.

Referring to FIG. 7, the semiconductor device 6 according to the sixth exemplary embodiment in accordance with principles of inventive concepts may include a plurality of capacitor groups 41 and a plurality of protection diodes 31. Each of the capacitor groups 41 may include a plurality of capacitors 1. At least one capacitor 1 may be placed in each capacitor group 41. Each capacitor 1 may be at least one of the above-described semiconductor devices 1 through 4 according to the first through fourth embodiments in accordance with principles of inventive concepts.

In an exemplary embodiment in accordance with principles of inventive concepts, a semiconductor device may be fabricated using a plasma process such as a physical vapor deposition (PVD) process or a sputtering process, for example. In such a process, charges (positive charges, negative charges) generated during the plasma process may be accumulated in the semiconductor device, and the charges may cause various defects. However, the protection diodes 31 can discharge the accumulated charges, thereby reducing the probability of defects caused by accumulated charges.

In an exemplary embodiment in accordance with principles of inventive concepts, one protection diode 31 may be provided for each capacitor group 41 (that is, for every predetermined number of capacitors 1) to rapidly discharge accumulated charges that may affect the capacitors 1, for example.

In an illustrated exemplary embodiment in accordance with principles of inventive concepts, one protection diode 31 is provided for every two capacitors 1 and the capacitors 1 may be connected in parallel, but inventive concepts are not limited thereto.

Referring to FIG. 8, the capacitors 1 may be arranged adjacent to each other in a first direction DR1.

In an exemplary embodiment in accordance with principles of inventive concepts, capacitor 1 includes an active region 110 defined by an element isolation region 118, a first well 112 formed in the active region 110, and a conductive layer 120 formed on the active region 110. A first insulating film 132 and a second insulating film 130 may be used as a capacitor insulating film. The first insulating film 132 may be formed between the first well 112 and the conductive layer 120, and the second insulating film 130 may be formed between the first well 112 and the conductive layer 120 and on at least part of a boundary between the element isolation region 118 and the active region 110. A plurality of first contacts 180 may be formed on the conductive layer 120. A plurality of second contacts 190 may be formed on the active region 110 (that is, on the first well 112) to be electrically connected to the first well 112.

In an exemplary embodiment in accordance with principles of inventive concepts, each protection diode 31 may include a well 612 of a first conductivity type and a junction region 165 of the first conductivity type. In FIG. 9, the p-type well 612 and the p+ junction 615 are illustrated as an example, but inventive concepts are not limited thereto. Each protection diode 31 may also include an n+ junction region within an n-type well, for example.

A plurality of capacitors 1 and at least one protection diode 31 may be formed on the same substrate 100, for example.

A first metal line 620 may connect the first contacts 180 to each other and may include a first part 620a extending in the first direction DR1 and second parts 620b branching from the first part 620a in a second direction DR2.

The second metal line 630 may connect the second contacts 190 to each other and may include a third part 630a extending in the first direction DR1 and fourth parts 630b branching from the third part 630a in the second direction DR2.

The capacitors 1 may be connected in parallel to each other by the first metal line 620 and the second metal line 630, for example.

In the exemplary embodiment of FIG. 9, a multilayer of metal lines MTL1 through MTL4 may be stacked sequentially on the capacitors 1 and the protection diodes 31.

The first metal line 620 may be the metal line MTL1 at a first level among the multilayer of the metal lines MTL1 through MTL4. The second metal line 630 may also be the metal line MTL1 at the first level, for example.

Charges generated by a plasma process may be accumulated in the conductive layer 120 or the first insulating film 132 and the second insulating film 130. The accumulated charges may be discharged to each protection diode 31 through the first contacts 180 and the first metal line 620 (or MTL1). That is, the accumulated charges may be discharged along a discharge path 550.

In exemplary semiconductor device 6 according to a sixth embodiment in accordance with principles of inventive concepts, the accumulated charges may be discharged to each protection diode 31 along the metal line MTL1 at the first level. That is, the accumulated charges are not discharged along the metal lines MTL2 through MTL4 at second or higher levels. In this manner, accumulated charges are discharged along a very short path, resulting in very high discharge efficiency.

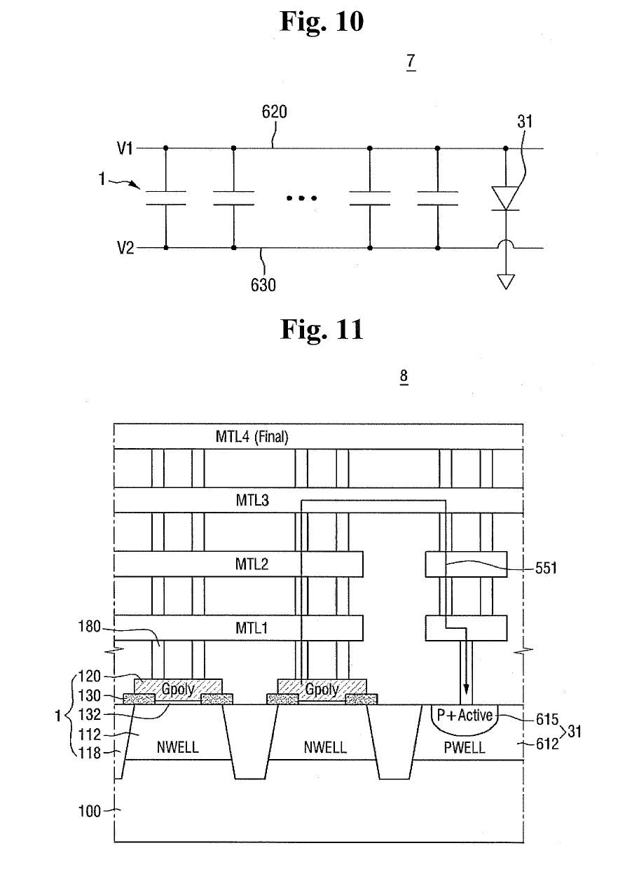

FIG. 10 is a circuit diagram of an exemplary embodiment of a semiconductor device 7 according to a seventh embodiment in accordance with principles of inventive concepts. For simplicity, the following description will focus on differences from the above-described semiconductor device 6 according to the sixth embodiment in accordance with principles of inventive concepts.

Referring to FIG. 10, while the semiconductor device 6 according to the sixth embodiment in accordance with principles of inventive concepts includes one protection diode 31 for every predetermined number of capacitors 1, the semiconductor device 7 according to the seventh embodiment in accordance with principles of inventive concepts includes one protection diode 31 connected to each first metal line 620. As a result, the semiconductor device 7 according to the seventh embodiment in accordance with principles of inventive concepts uses a relatively small number of protection diodes 31 and this may reduce the layout area used to form the protection diodes 31.

FIG. 11 is a cross-sectional view of a semiconductor device 8 according to an eighth embodiment in accordance with principles of inventive concepts. For simplicity, the following description will focus on differences from the above-described semiconductor device 6 according to the sixth embodiment in accordance with principles of inventive concepts

Referring to FIG. 11, in the semiconductor device 8 according to the eighth embodiment in accordance with principles of inventive concepts, charges generated by a plasma process may be accumulated in a conductive layer 120 or a first insulating film 132 and a second insulating film 130. The accumulated charges may be discharged to a protection diode 31 through a plurality of first contacts 180 and a multilayer of metal lines MTL1 through MTL3. That is, the accumulated charges may be discharged along a discharge path 551 shown in the drawing.

The semiconductor device 8 according to the eighth embodiment in accordance with principles of inventive concepts can be used when it is difficult to place a plurality of capacitors 1 adjacent to a protection diode 31 or when it is difficult to connect the capacitors 1 and the protection diode 31 to the metal line MTL1 at a first level, for example.

In the exemplary embodiment, the discharge path 551 is illustrated as being formed by the metal lines MTL1 through MTL3. However, the discharge path 551 may also be formed by MTL1 through MTL4 or MTL1 and MTL2, for example.

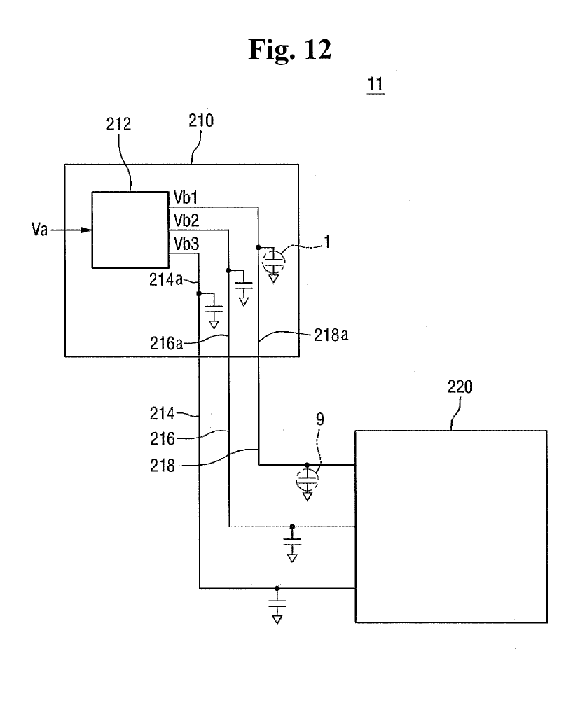

FIG. 12 is a block diagram of a semiconductor system 11 according to a first exemplary embodiment in accordance with principles of inventive concepts.

Referring to FIG. 12, the semiconductor system 11 may include a semiconductor chip 210 and a module 220 which are electrically connected to each other.

The semiconductor chip 210 may be a chip that includes a processor, a memory, a logic circuit, an audio and image processing circuit and various interface circuits, such as a system on chip (SOC), a microcontroller unit (MCU), or a display driver IC (DDI), for example. The semiconductor chip 210 may include MOS transistors having various driving voltages: for example, a high-voltage transistor, a medium-voltage transistor, and a low-voltage transistor.

The semiconductor chip 210 may include a voltage generator 212 that receives an external voltage Va and generates one or more internal voltages Vb1 through Vb3. The semiconductor chip 210 may also include one or more internal wirings 214a, 216a and 218a for delivering the internal voltages Vb1 through Vb3.

Capacitors 1 for stably delivering the internal voltage Vb1 through Vb3 may be connected to the internal wirings 214a, 216a, and 218a and capacitors 9 for stably delivering the internal voltages Vb1 through Vb3 may be connected to external wirings 214, 216 and 218. In this exemplary embodiment, capacitors 1 are internal capacitors embedded in the semiconductor chip 210, and the capacitors 9 are external capacitors mounted outside the semiconductor chip 210. Each of the capacitors 1 may be any one of the above-described semiconductor devices 1 through 8 according to the first through eighth embodiments in accordance with principles of inventive concepts. One internal capacitor 1 may be connected to each internal wiring 214a, 216a or 218a, and one external wiring 9 may be connected to each external wiring 214, 216 or 218, for example.

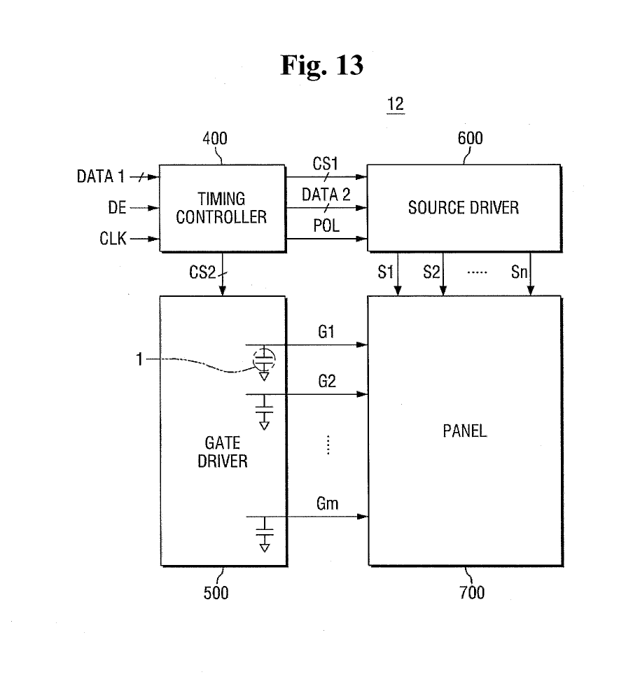

FIG. 13 is a block diagram of a semiconductor system 12 according to a second exemplary embodiment in accordance with principles of inventive concepts. The semiconductor system 12 of FIG. 13 may be a more detailed form of the semiconductor system 11 of FIG. 12, for example. The semiconductor system 12 of FIG. 13 may be a display device, in which case, the semiconductor chip 210 of FIG. 12 may correspond to a gate driver 500, and the module 22 may correspond to a panel 700, for example. The semiconductor system 12 according to the second exemplary embodiment in accordance with principles of inventive concepts may include a timing controller 400, the gate driver 500, a source driver 600, and the panel 700.

In an exemplary embodiment, the panel 700 includes a plurality of gate lines G1 through Gm, a plurality of source lines S1 through Sn, and a plurality of pixels (not shown). Each of the pixels is electrically connected to a corresponding one of the gate lines G1 through Gm and a corresponding one of the source lines Si through Sn.

The timing controller 400 may generate a first control signal CS1, a second control signal CS2, data DATA2 and a polarity control signal POL based on data DATA1, a data enable signal DE, and a clock signal CLK.

The gate driver 500 drives the gate lines G1 through Gm in response to the second control signal S2. The source driver 600 outputs an analog voltage to the source lines S1 through Sn in response to the first control signal CS1, the data DATA2, and the polarity control signal POL. The analog voltage is inverted with respect to a common voltage of the panel 700 in response to the polarity control signal POL.

Capacitors 1 may be embedded in the gate driver 500, for example. Each of the capacitors 1 may be any one of the above-described semiconductor devices 1 through 8 according to the first through eighth embodiments in accordance with principles of inventive concepts.

Although the capacitors 1 are embedded in the gate driver 500 in FIG. 13, they can also be embedded in the source driver 600, the timing controller 400, or another semiconductor chip not shown in the drawing, for example.

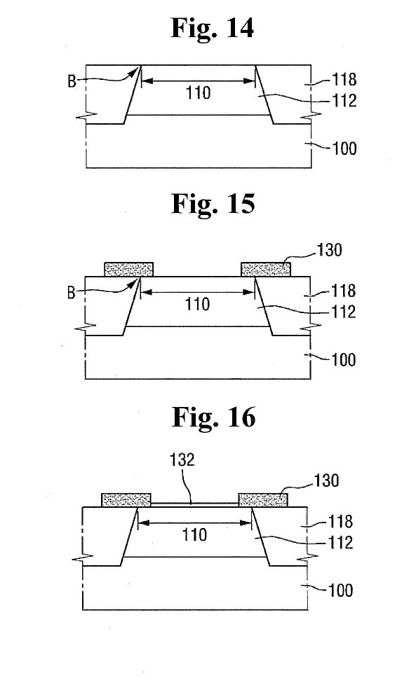

A method of fabricating the semiconductor device 1 according to the first exemplary embodiment in accordance with principles of inventive concepts will be described with reference to FIGS. 14 through 16 and 2. FIGS. 14 through 16 are diagrams illustrating intermediate processes included in a method of fabricating the semiconductor device 1 according to the first exemplary embodiment in accordance with principles of inventive concepts.

Referring to FIG. 14, an element isolation region 118 is formed in a substrate 100 to define an active region 110. A first well 112 is formed in the active region 110.

In FIG. 15 a second insulating film 130 having a second thickness is formed on at least part of a boundary B between the active region 110 and the element isolation region 118. For example, a fourth insulating film (e.g., an oxide film) may be formed to a thickness of from approximately 300 Å to 1200 Å on the resultant structure of FIG. 14 using a CVD method and then patterned, thereby forming the second insulating film 130.

In FIG. 16 a first insulating film 132 having a first thickness is formed on a portion of the active region 110 exposed by the second insulating film 130. For example, the first insulating film 132 may be formed to a thickness of from approximately 10 Å to 300 Å using a thermal oxidation method.

Referring to FIG. 2, a conductive layer 120 is formed on the first insulating film 132 and the second insulating film 130, thereby completing the semiconductor device 1 according to the first exemplary embodiment in accordance with principles of inventive concepts. For example, a pre-conductive layer may be formed on the resultant structure of FIG. 16, and then an electrode conductive layer may be patterned and then patterned to complete the conductive layer 120 that serves as an electrode of a capacitor.

A method of fabricating the semiconductor device 5 according to the fifth exemplary embodiment in accordance with principles of inventive concepts will now be described with reference to FIGS. 17 through 20 and 6. FIGS. 17 through 20 are diagrams illustrating intermediate processes included in a method of fabricating the semiconductor device 5 according to the fifth exemplary embodiment in accordance with principles of inventive concepts.

In FIG. 17 an element isolation region 118 is formed in a substrate 100 to define first through third regions, I through III. The first region I is a region in which a capacitor 1 is to be formed, the second region II is a region in which a first MOS transistor 21 is to be formed, and the third region III is a region in which a second MOS transistor 22 is to be formed. The first MOS transistor 21 may be a high-voltage transistor, and the second MOS transistor 22 may be a medium-voltage transistor or a low-voltage transistor, for example.

In an exemplary embodiment, a first well 112 is formed in the first region I, a second well 312 is formed in the second region II, and a third well 362 is foamed in the third region III. The first well 112 and the third well 362 may be formed simultaneously using the same dopants.

A fourth insulating film 130b may be formed to a second thickness (for example, from approximately 300 Å to 1200 Å) on the first through third regions I through III by CVD.

Referring to FIG. 18, a mask (not shown) is formed on the fourth insulating film 130b, and the fourth insulating film 130b is patterned using the mask to produce the fourth insulating film 130a and 330a. The fourth insulating film 130a and 330a may cover at least part of a boundary B between the element isolation region 118 and an active region 110 in the first region I, cover the entire second region II, and expose the entire third region III.

Referring to FIG. 19, a third insulating film 132 and 332a may be formed on the substrate 100 to a first thickness that is less than the second thickness. The third insulating film 132 and 332a covers exposed portions of the substrate 100 in the first region I and the third region III. The third insulating film 132 and 332a may be formed by thermal oxidation, for example.

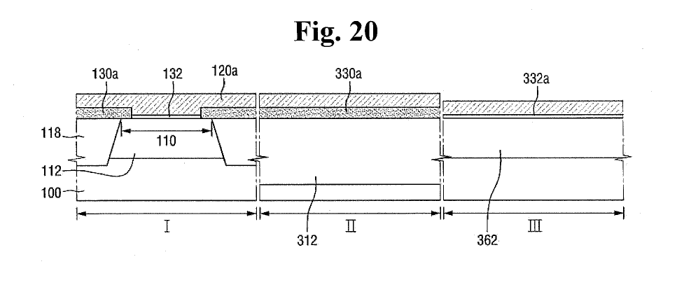

Referring to FIG. 20, an electrode conductive layer 120a may be formed on the substrate 100 having the third insulating film 132 and 332a and the fourth insulating film 130a and 330a.

In the process depicted in FIG. 6, the electrode conductive layer 120a, the third insulating film 132 and 332a, and the fourth insulating film 130a and 330a are patterned, thereby forming a conductive layer 120, a second insulating film 130, a first gate electrode 320, a first gate insulating film 330, a second gate electrode 370, and a second gate insulating film 332.

As described above with reference to FIGS. 17 through 20 and 6, no additional masks are required to fabricate the semiconductor device 4 according to the fourth exemplary embodiment in accordance with principles of inventive concepts. That is, the semiconductor device 4 can be completed using a mask used to form the first MOS transistor 21 and the second MOS transistor 22.

While exemplary embodiments in accordance with principles of inventive concepts have been particularly shown and described, it will be understood that various changes in form and detail may be made therein without departing from the spirit and scope of inventive concepts as defined by the following claims. The exemplary embodiments should be considered in a descriptive sense only and not for purposes of limitation.

1. A semiconductor device comprising:
an element isolation region formed in a substrate and defining an active region;
a conductive layer formed on the active region;
a first insulating film formed between the active region and the conductive layer and having a first thickness; and
a second insulating film formed between the active region and the conductive layer and spanning at least part of a boundary between the active region and the element isolation region and having a second thickness which is greater than the first thickness.

2. The semiconductor device of claim 1, wherein the first insulating film comprises a thermal oxide film, and the second insulating film comprises a chemical vapor deposition (CVD) film.

3. The semiconductor device of claim 1, wherein a region of the conductive layer overlaps the element isolation region, and contacts are formed on the overlapping region of the conductive layer.

4. The semiconductor device of claim 1, wherein the active region comprises a first side and a second side parallel to one another, and the second insulating film comprises a first partial insulating film which covers at least part of the first side and a second partial insulating film which covers at least part of the second side.

5. The semiconductor device of claim 1, wherein the conductive layer comprises a first partial conductive layer having a first width and a second partial conductive layer having a second width which is different from the first width, wherein the second partial conductive layer overlaps the element isolation region.

6. The semiconductor device of claim 5, wherein the active region includes a groove cut into the active region, and the second partial conductive layer overlaps the groove.

7. The semiconductor device of claim 5, wherein the first partial conductive layer overlaps the entire active region.

8. The semiconductor device of claim 1, further comprising a first metal oxide semiconductor (MOS) transistor having a first operating voltage and a second MOS transistor having a second operating voltage that is lower than the first operating voltage.

9. The semiconductor device of claim 8, further comprising a third MOS transistor having a third operating voltage that is lower than the second operating voltage.

10. The semiconductor device of claim 8, wherein a thickness of a first gate insulating film of the first MOS transistor is equal to the second thickness of the second insulating film, and a thickness of a second gate insulating film of the second MOS transistor is equal to the first thickness of the first insulating film.

11. The semiconductor device of claim 8, wherein a first well is formed in the active region, the first MOS transistor comprises a second well, and the second MOS transistor comprises a third well, wherein the first well and the third well are doped with the same dopants.

12. The semiconductor device of claim 11, wherein the first well and the third well are formed to the same depth.

13. The semiconductor device of claim 1, wherein parts of a lateral profile of the conductive layer are aligned with parts of a lateral profile of the second insulating film.

14. The semiconductor device of claim 1, wherein the conductive layer is electrically connected to a metal line, and the metal line is electrically connected to a protection diode formed in the substrate.

15. The semiconductor device of claim 14, wherein the metal line is a metal line at a first level.

16. The semiconductor device of claim 1, wherein the element isolation region comprises a shallow trench isolation (STI) region.

17. The semiconductor device of claim 1, wherein the device is a capacitor.

18. A semiconductor device comprising a capacitor, a first MOS transistor, and a second MOS transistor, wherein an operating voltage of the first MOS transistor is higher than an operating voltage of the second MOS transistor, the capacitor uses a first insulating film and a second insulating film as a capacitor insulating film, a first thickness of the first insulating film is equal to a thickness of a second gate insulating film of the second MOS transistor, and a second thickness of the second insulating film is equal to a thickness of a first gate insulating film of the first MOS transistor.

19. The semiconductor device of claim 18, wherein the capacitor is a MOS-type capacitor.

20. The semiconductor device of claim 19, wherein the capacitor is formed on an active region defined by an element isolation region, and the second insulating film spans at least part of a boundary between the element isolation region and the active region.

21. The semiconductor device of claim 20, wherein the capacitor further comprises a conductive layer that is formed on the first insulating film and the second insulating film and overlaps the element isolation region, wherein contacts are formed on a region of the conductive layer that overlaps the element isolation region.

22. The semiconductor device of clam 18, wherein the first insulating film comprises a thermal oxide film, and the second insulating film comprises a CVD oxide film.

23. The semiconductor device of claim 18, wherein parts of a lateral profile of the conductive layer are aligned with parts of a lateral profile of the second insulating film.

24. A semiconductor device comprising a plurality of capacitors and at least one protection diode which protects the capacitors by discharging charges generated by a plasma process, wherein each of the capacitors comprises:
an element isolation region formed in a substrate and defining an active region;
a conductive layer formed on the active region;
a first insulating film formed between the active region and the conductive layer and having a first thickness; and
a second insulating film formed between the active region and the conductive layer and spans at least part of a boundary between the active region and the element isolation region and having a second thickness which is greater than the first thickness.

25. The semiconductor device of claim 24, wherein the conductive layer of each of the capacitors is electrically connected to the at least one protection diode by a metal line.

26. The semiconductor device of claim 25, wherein the metal line is a metal line at a first level.

27. The semiconductor device of claim 24, wherein the capacitors are divided into a plurality of capacitor groups, and at least one protection diode is provided for each capacitor group.

28. The semiconductor device of claim 24, wherein the first insulating film comprises a thermal oxide film, and the second insulating film comprises a CVD oxide film.

29. The semiconductor device of claim 24, wherein the capacitors and the at least one protection diode are formed on the same substrate.

30. The semiconductor device of claim 24, wherein the capacitors are connected in parallel to each other.

31.-52. (canceled)
